(19) United States
(12) Patent Application Publication
(10) Pub. No.: US 2010/0101496 A1
(43) Pub. Date: Apr. 29, 2010

(54) WAFER CARRIER AND EPITAXY MACHINE USING THE SAME

(75) Inventors: CHIH CHING CHENG, TAICHUNG CITY (TW); TZONG-LIANG TSAI, TAICHUNG (TW)

Correspondence Address: WPAT, PC;INTELLECTUAL PROPERTY ATTORNEYS, 2030 MAIN STREET, SUITE 1300, IRVINE, CA, 92614, US

(73) Assignee: HUGA OPTOTECH INC., TAICHUNG CITY (TW)

(21) Appl. No.: 12/648,849

(22) Filed: Dec. 29, 2009

Related U.S. Application Data
(62) Division of application No. 12/194,013, filed on Aug. 19, 2008.

(51) Int. Cl. C23C 16/00

(52) U.S. Cl. 118/728

(57) ABSTRACT

A wafer carrier comprises a base and a shielding plate positioned on the top surface of the base in a disassembled manner. The top surface of the base is configured to retain a plurality of wafers, and the shielding plate has a plurality of openings exposing the wafers. In particular, the shielding plate shields one portion of the base other than the other portions occupied by the wafers to prevent the reaction gases from conducting the chemical reaction to generate the reactant directly on the surface of the base. Consequently, the base is isolated from the chemical reaction, and it is not necessary to replace the base before conducting the next fabrication process or to clean the reactants on the surface of the base by thermal baking or etching.

This present application is a divisional application of U.S. patent application Ser. No. 12/194,013, filed on Aug. 19, 2008, which claims foreign priority 097122071 filed on Jun. 13, 2008, and the disclosure of which is incorporated herein by reference.

### BACKGROUND OF THE INVENTION

(A) Field of the Invention

The present invention relates to a wafer carrier and epitaxy machine using the same, and more particularly, to a wafer carrier using a replaceable shielding plate to prevent reaction gases from generating products directly on the surface of a base and an epitaxy machine using the same.

(B) Description of the Related Art

III-V compounds have been widely applied to the optical devices such as high luminance light-emitting diode (LED) and laser diode. The light-emitting structure of these optical devices has been improved from the early p/n junction structure, heterojunction structure to the multi-layer quantum well structure, and the luminance increases with improvements in light-emitting structure technology. The light-emitting structures such as the heterojunction structure and the multi-layer quantum well structure are formed on the semiconductor substrate by the molecular beam epitaxy technique or the chemical vapor phase deposition technique. In particular, the metal organic chemical vapor deposition (MOCVD) has become the most widely used technique for preparing the light-emitting structure.

MOCVD apparatus includes a processing chamber, a graphite base configured to retain wafers in the processing chamber, and gas lines configured to transfer reaction gases to the surface of the wafers in the processing chamber. During the deposition process, the semiconductor substrate is placed on the graphite base and heated to a reaction temperature, and the reaction gases are then transferred to the surface of the wafers in the processing chamber via the gas lines such that the chemical reaction occurs and forms layers on the surface of the wafers in the processing chamber.

The reaction gases are transferred not only to the surface of the wafers, but also to the graphite base where the reaction occurs to form reaction product on the graphite base. Therefore, before replacing the semiconductor substrate to conduct the next deposition process, the processing chamber is baked at high temperature or an etching process is performed to remove the reaction process formed on the surface of the graphite base. Then, the same graphite base can be used in the next deposition process; however, the processing time is obviously longer. To shorten the fabrication time, the prior art replaces the graphite base after each deposition process; however, the thermal conductivity is inconsistent from one graphite base to another, and replacing the graphite base after each deposition process results in greater difficulty in controlling the semiconductor substrate temperature, and consequently reduced temperature control leads to poor yield.

### SUMMARY OF THE INVENTION

One aspect of the present invention provides a wafer carrier using a replaceable shielding plate to prevent reaction gases from generating products directly on the surface of a base and an epitaxy machine using the same.

A wafer carrier according to this aspect of the present invention comprises a base having a top surface configured to retain a plurality of wafers and a shielding plate positioned on the top surface of the base in a disassembled manner, wherein the shielding plate has a plurality of openings exposing the wafers.

Another aspect of the present invention provides an epitaxy machine comprising a processing chamber, a plurality of inlets coupled to the processing chamber, a shaft having an upper end in the processing chamber, and a wafer carrier positioned on the upper end.

Compared to the prior art, the shielding plate of the present application covers the portion of the base not configured to retain the wafers to prevent the reaction gases from generating reaction products on the top surface of the base. Consequently, it is not necessary to replace the base before performing the next deposition process, to bake the processing chamber at high temperature to remove the reaction products on the top surface, or to perform an etching process to remove the reaction products on the top surface.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 illustrates a cross-sectional view of an epitaxy machine according to the first embodiment of the present invention;

FIG. 2 illustrates a disassembled view of a wafer carrier according to the first embodiment of the present invention;

FIG. 3 illustrates a partial cross-sectional view of the wafer carrier according to the first embodiment of the present invention;

FIG. 4 illustrates a cross-sectional view of a wafer carrier according to the second embodiment of the present invention;

FIG. 5 illustrates a disassembled view of an epitaxy machine according to the second embodiment of the present invention;

FIG. 6 illustrates a partial cross-sectional view of the wafer carrier according to the second embodiment of the present invention;

FIG. 7 illustrates a cross-sectional view of an epitaxy machine according to the third embodiment of the present invention;

FIG. 8 illustrates a disassembled view of a wafer carrier according to the third embodiment of the present invention;

FIG. 9 illustrates a partial cross-sectional view of an epitaxy machine according to the third embodiment of the present invention;

FIG. 10 illustrates a cross-sectional view of an epitaxy machine according to the fourth embodiment of the present invention;

FIG. 11 illustrates a disassembled view of a wafer carrier according to the fourth embodiment of the present invention; and

FIG. 12 illustrates a partial cross-sectional view of the wafer carrier according to the fourth embodiment of the present invention.

### DETAILED DESCRIPTION OF THE INVENTION

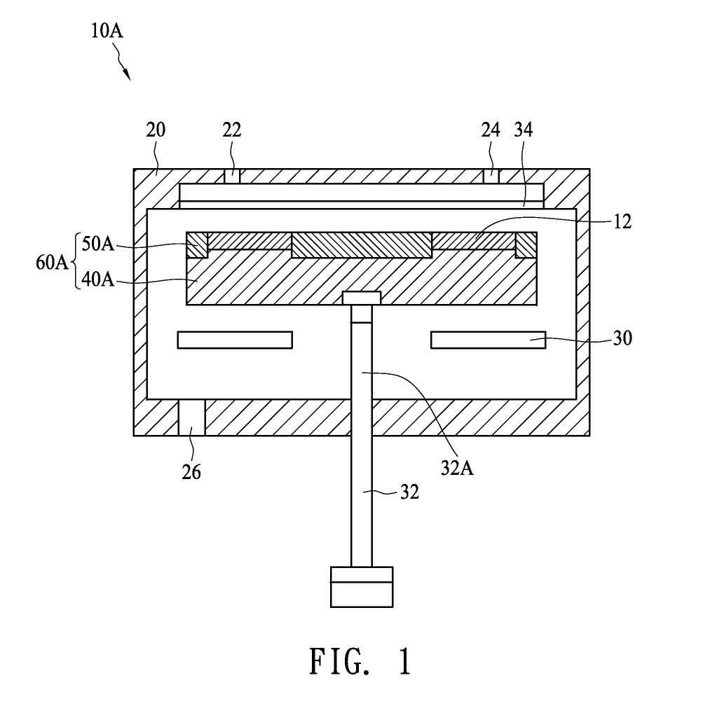

FIG. 1 to FIG. 3 illustrate an epitaxy machine 10A according to a first embodiment of the present invention. Referring to FIG. 1, which is a cross-sectional view of the epitaxy machine 10A according to the first embodiment of the present invention, the epitaxy machine 10A comprises a processing chamber 20, a showerhead 34 positioned on an upper portion of the processing chamber 20, a first inlet 22 coupled to the processing chamber 20 and configured to transfer a first reactant to the processing chamber 20, a second inlet 24 coupled to the processing chamber 20 and configured to transfer a second reactant to the processing chamber 20, an outlet 26 configured to transfer exhaust gases from the processing chamber 20, a shaft 32 having an upper end 32A in the processing chamber 20, a wafer carrier 60A positioned on the upper end 32A, and a heater 30 positioned below the wafer carrier 60A.

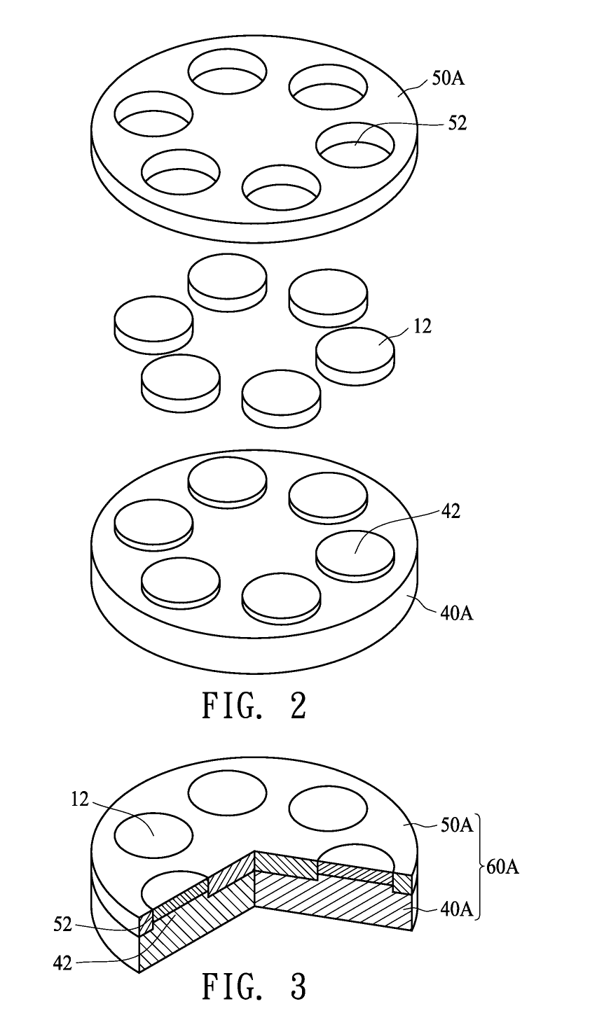

FIG. 2 is a disassembled view of the wafer carrier 60A according to the first embodiment of the present invention, and FIG. 3 is a partial cross-sectional view of the wafer carrier 60A according to the first embodiment of the present invention. The wafer carrier 60A comprises a base 40A and a shielding plate 50A. The base 40A has a plurality of protrusions (retaining regions) 42 on the top surface for retaining several wafers 12. The base 40A can be a graphite base, which is coated with a layer of silicon carbide in advance for protecting the graphite base from the corrosive effect of the reaction gases.

The shielding plate 50A is positioned on the top surface of the base 40A in a disassembled manner, and has a plurality of openings 52 exposing the protrusions 42 of the base 40A, and the openings 52 are circular and have a diameter substantially equal to the diameter of the wafer 12. The thickness of the shielding plate 50A substantially equals the thickness of the protrusion 42 plus the thickness of the wafer 12. The protrusion 42 of the base 40A can fix the shielding plate 50A on the top surface of the base 40A, and the shielding plate 50A will not depart from the base 40A as the shaft 32 rotates the wafer carrier 60A.

In particular, the shielding plate 50A covers a portion of the top surface of the base 40A other than the protrusions 42, i.e., the other portion of the top surface not configured to retain the wafers 12, such that the reaction product is formed on the shielding plate 50A rather than directly formed on the top surface of the base 40A. Consequently, it is not necessary for the operators to replace the base 40A before performing the next deposition process, to bake the processing chamber 20 at high temperature to remove the reaction products on the top surface, or to perform an etching process to remove the reaction products on the top surface.

Furthermore, since the shielding plate 50A is positioned on the top surface of the base 40A in a disassembled manner, the operators need only to replace the old shielding plate 50A with a new one before performing the next deposition process, instead of replacing the base 40A after each deposition process. Consequently, the thermal conductivity of the base 40A is the same, and the temperature of the wafer 12 on the base 40A can be easily controlled to increase the yield.

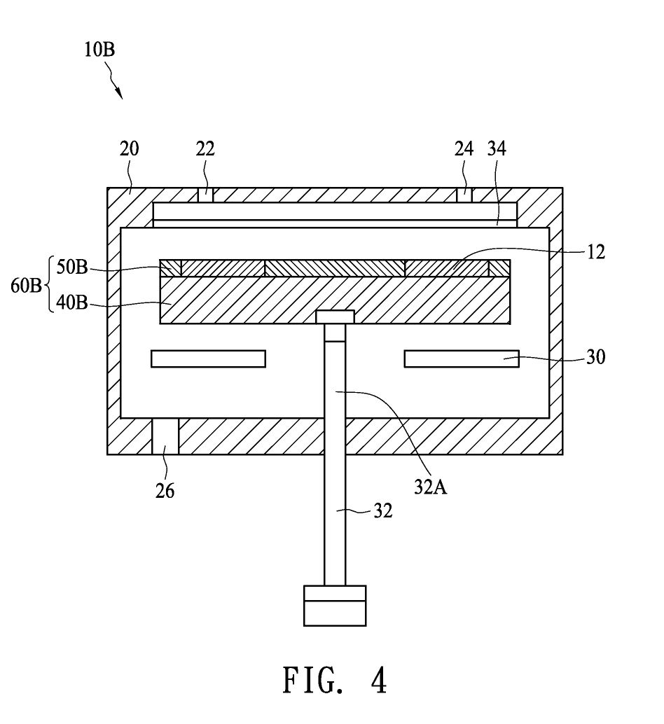

FIG. 4 to FIG. 6 illustrate an epitaxy machine 10B according to a second embodiment of the present invention. FIG. 4 is a cross-sectional view of the epitaxy machine 10B according to the second embodiment of the present invention. The epitaxy machine 10B comprises a processing chamber 20, a showerhead 34 positioned on an upper portion of the processing chamber 20, a first inlet 22 coupled to the processing chamber 20 and configured to transfer a first reactant to the processing chamber 20, a second inlet 24 coupled to the processing chamber 20 and configured to transfer a second reactant to the processing chamber 20, an outlet 26 configured to transfer exhaust gases from the processing chamber 20, a shaft 32 having an upper end 32A in the processing chamber 20, a wafer carrier 60B positioned on the upper end 32A, and a heater 30 positioned below the wafer carrier 60B.

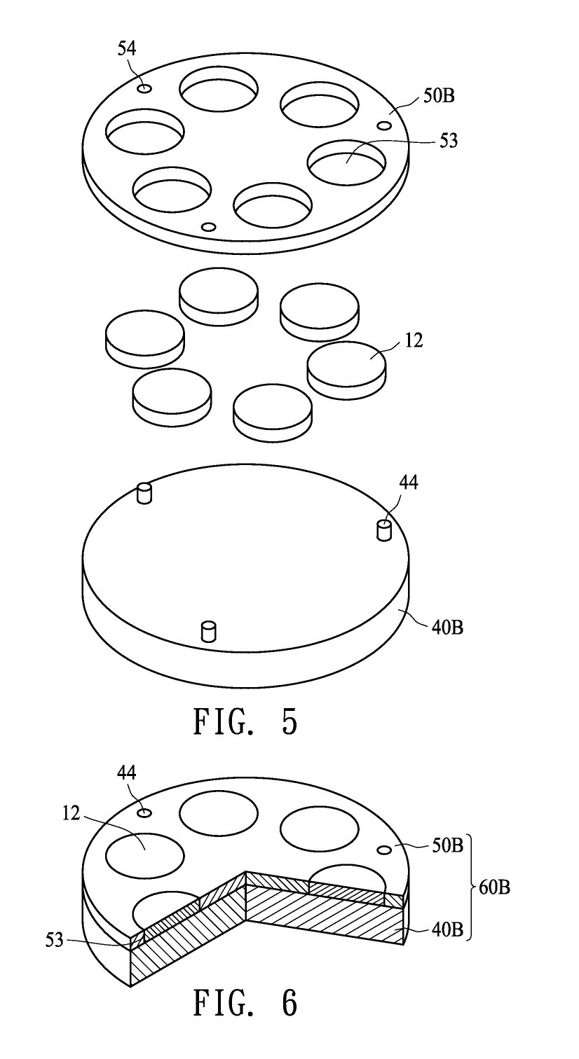

FIG. 5 is a disassembled view of the wafer carrier 60B according to the second embodiment of the present invention, and FIG. 6 is a partial cross-sectional view of the wafer carrier 60B according to the second embodiment of the present invention. The wafer carrier 60B comprises a base 40B and a shielding plate 50B positioned on the top surface of the base 40B in a disassembled manner. The base 40B can be a graphite base, which is coated with a layer of silicon carbide in advance for protecting the graphite base from the corrosive effect of the reaction gases.

The top surface of the base 40B is a planar surface, which can retain several wafers 12. The shielding plate 50A has a plurality of openings 53 exposing the wafers 12. The thickness of the shielding plate 50B substantially equals the thickness of the wafer 12. The wafer carrier 60B further comprises a fixing member 44 such as bolts configured to fix the shielding plate 50B on the base 40B by the interference with the holes 54 of the shielding plate 50B such that the shielding plate 50B will not depart from the base 40B as the shaft 32 rotates the wafer carrier 60B.

In particular, the shielding plate 50B covers a portion of the top surface not configured to retain the wafers 12, such that the reaction product is formed on the shielding plate 50B rather than directly on the top surface of the base 40B. Consequently, it is not necessary for the operators to replace the base 40B before performing the next deposition process, to bake the processing chamber 20 at high temperature to remove the reaction products on the top surface, or to perform an etching process to remove the reaction products on the top surface.

Furthermore, since the shielding plate 50B is positioned on the top surface of the base 40B in a disassembled manner, the operators need only to replace the used shielding plate 50B with a new one before performing the next deposition process, instead of replacing the base 40B after each deposition process. Consequently, the thermal conductivity of the base 40B can be kept consistent, and the temperature of the wafer 12 on the base 40B can be easily controlled to increase the yield.

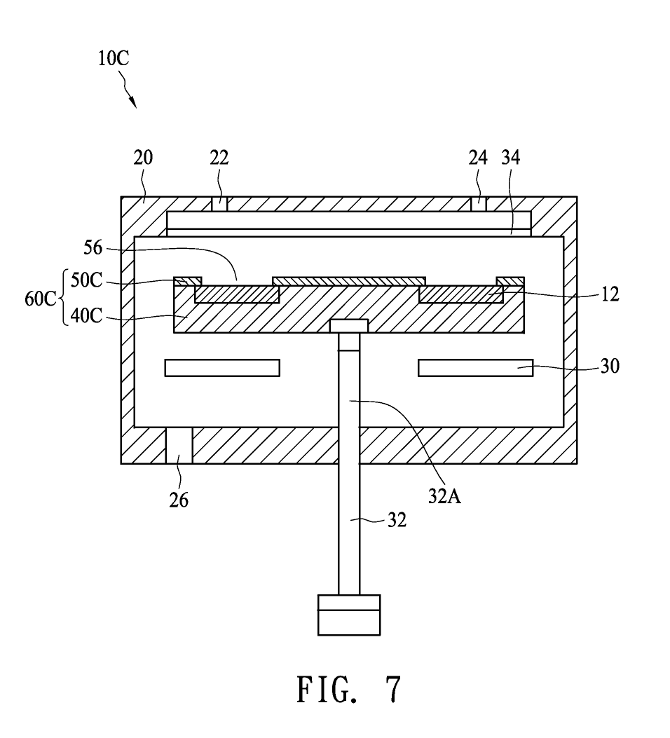

FIG. 7 to FIG. 9 illustrate an epitaxy machine 10C according to a third embodiment of the present invention. FIG. 7 is a cross-sectional view of the epitaxy machine 10C according to the third embodiment of the present invention. The epitaxy machine 10C comprises a processing chamber 20, a showerhead 34 positioned on an upper portion of the processing chamber 20, a first inlet 22 coupled to the processing chamber 20 and configured to transfer a first reactant to the processing chamber 20, a second inlet 24 coupled to the processing chamber 20 and configured to transfer a second reactant to the processing chamber 20, an outlet 26 configured to transfer exhaust gases from the processing chamber 20, a shaft 32 having an upper end 32A in the processing chamber 20, a wafer carrier 60C positioned on the upper end 32A, and a heater 30 positioned below the wafer carrier 60C.

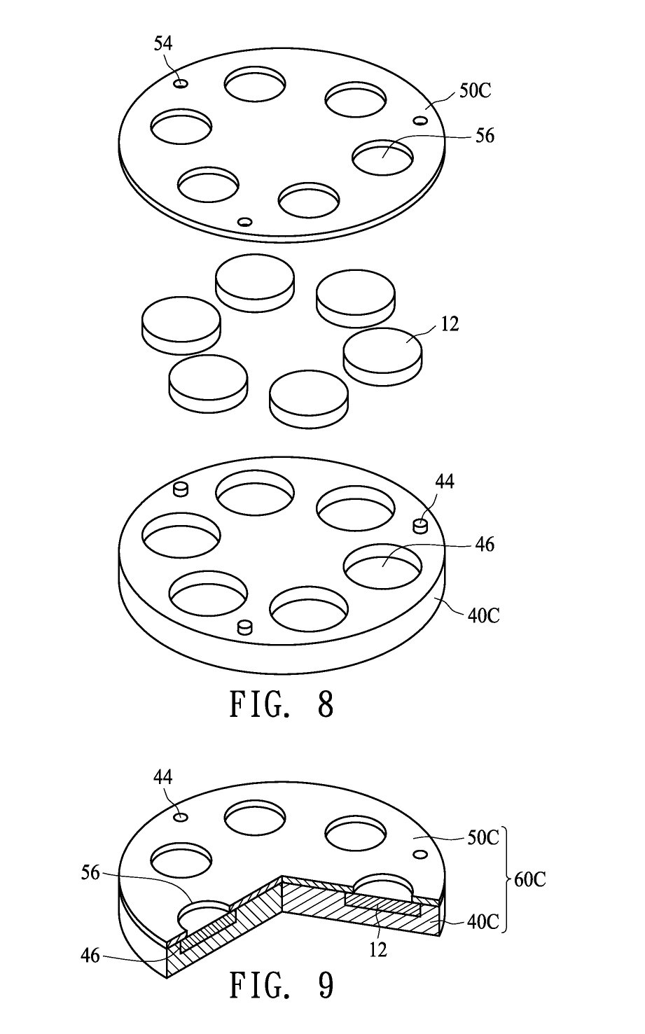

FIG. 8 is a disassembled view of the wafer carrier 60C according to the third embodiment of the present invention, and FIG. 9 is a partial cross-sectional view of the wafer carrier 60C according to the third embodiment of the present invention. The wafer carrier 60C comprises a base 40C and a shielding plate 50C. The base 40C includes a plurality of depressions (retaining regions) 46 on the top surface, and the depressions 46 are configured to retain several wafers 12. The depth of the depression 46 substantially equals the thickness of the wafer 12. Generally, the base 40C can be a graphite base, which has been coated with a layer of silicon carbide in advance for protecting the graphite base from the corrosive effect of the reaction gases.

The shielding plate 50C is positioned on the top surface of the base 40C in a disassembled manner, and has a plurality of openings 56 exposing the depressions 46 of the base 40C. The openings 56 are circular and have a diameter substantially smaller than the diameter of the wafer 12, i.e., the shielding plate 50C covers an edge portion of the wafers 12. The diameter of the openings 56 can be optionally designed to substantially equal the diameter of the wafers 12. The wafer carrier 60C further comprises a fixing member 44 such as bolts configured to fix the shielding plate 50C on the base 40C by the interference with the holes 54 of the shielding plate 50C such that the shielding plate 50C will not depart from the base 40C as the shaft 32 rotates the wafer carrier 60B.

In particular, the shielding plate 50C covers a portion of the top surface other than the depressions 56, i.e., the other portion not configured to retain the wafers 12 is covered by the shielding plate 50C, such that the reaction product is formed on the shielding plate 50C rather than directly on the top surface of the base 40B. Consequently, it is not necessary for the operators to replace the base 40C before performing the next deposition process, to bake the processing chamber 20 at high temperature to remove the reaction products on the top surface, or to perform an etching process to remove the reaction products on the top surface.

Furthermore, since the shielding plate 50C is positioned on the top surface of the base 40C in a disassembled manner, the operators need only to replace the used shielding plate 50C with a new one before performing the next deposition process, instead of replacing the base 40C after each deposition process. Consequently, the thermal conductivity of the base 40C can be kept consistent, and the temperature of the wafer 12 on the base 40C can be easily controlled to increase yield.

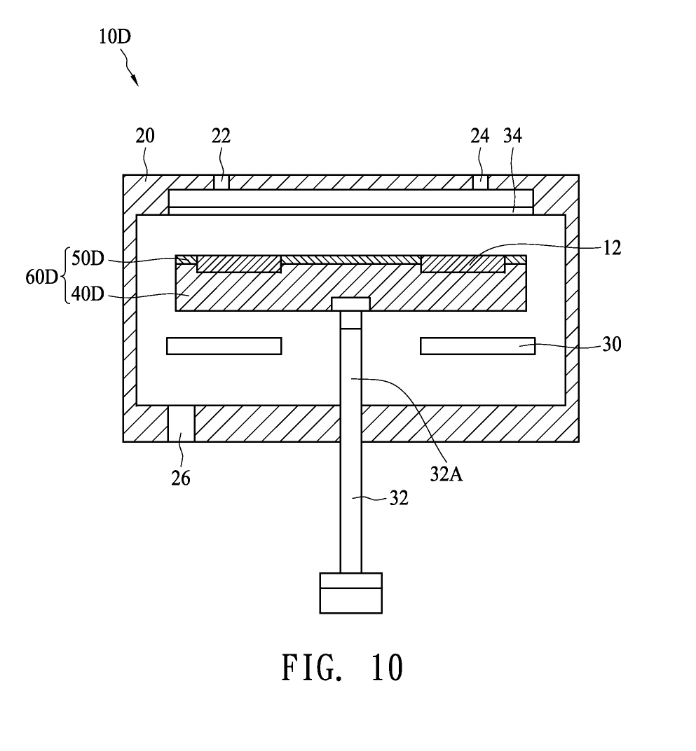

FIG. 10 to FIG. 12 illustrate an epitaxy machine 10D according to a fourth embodiment of the present invention. FIG. 10 is a cross-sectional view of the epitaxy machine 10D according to the fourth embodiment of the present invention. The epitaxy machine 10D comprises a processing chamber 20, a shower head 34 positioned on an upper portion of the processing chamber 20, a first inlet 22 coupled to the processing chamber 20 and configured to transfer a first reactant to the processing chamber 20, a second inlet 24 coupled to the processing chamber 20 and configured to transfer a second reactant to the processing chamber 20, an outlet 26 configured to transfer exhaust gases from the processing chamber 20, a shaft 32 having an upper end 32A in the processing chamber 20, a wafer carrier 60D positioned on the upper end 32A, and a heater 30 positioned below the wafer carrier 60D.

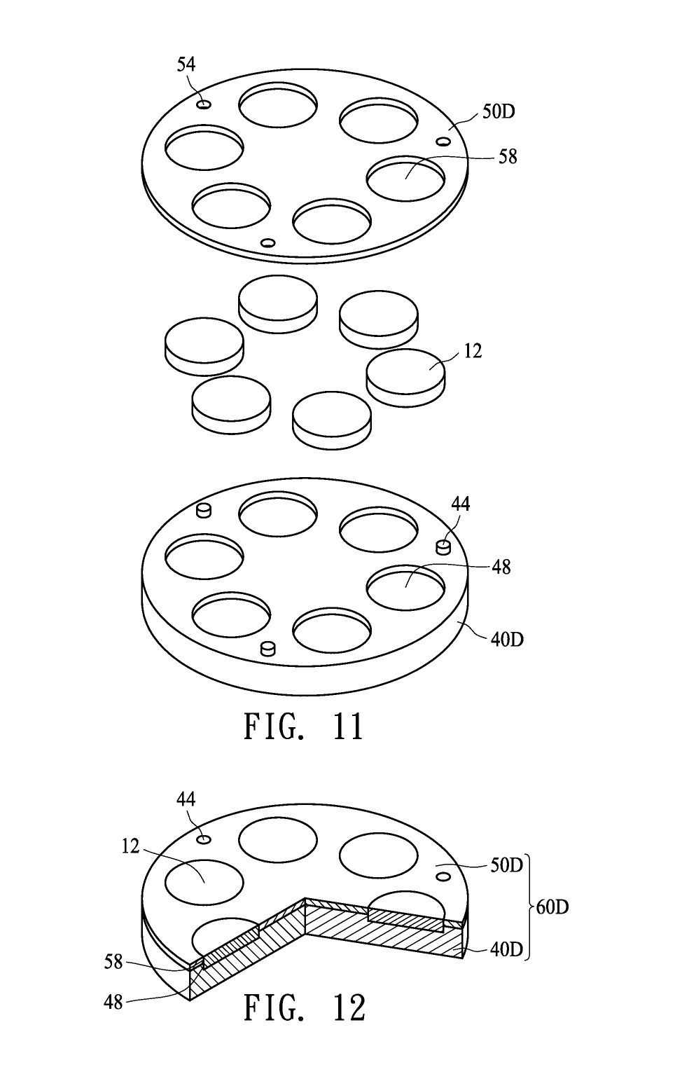

FIG. 11 is a disassembled view of the wafer carrier 60D according to the fourth embodiment of the present invention, and FIG. 12 is a partial cross-sectional view of the wafer carrier 60D according to the fourth embodiment of the present invention. The wafer carrier 60D comprises a base 40D and a shielding plate 50C. The base 40D includes a plurality of depressions (retaining regions) 48 on the top surface, and the depressions 48 are configured to retain several wafers 12. The thickness of the wafer 12 substantially equals the thickness of the shielding plate 50d plus the depth of the depression 48. Generally, the base 40D can be a graphite base, which is coated with a layer of silicon carbide in advance for protecting the graphite base from the corrosive effect of the reaction gases.

The shielding plate 50D is positioned on the top surface of the base 40D in a disassembled manner, and has a plurality of openings 58 exposing the depressions 48 of the base 40C. The openings 58 are circular and have a diameter substantially equal to the diameter of the wafer 12. The wafer carrier 60D further comprises a fixing member 44 such as bolts configured to fix the shielding plate 50D on the base 40D by the interference with the holes 54 of the shielding plate 50D such that the shielding plate 50D will not depart from the base 40D as the shaft 32 rotates the wafer carrier 60B.

In particular, the shielding plate 50D covers a portion of the top surface other than the depressions 58, i.e., the other portion not configured to retain the wafers 12 is covered by the shielding plate 50D, such that the reaction product is formed on the shielding plate 50D rather than directly on the top surface of the base 40B. Consequently, it is not necessary for the operators to replace the base 40D before performing the next deposition process, to bake the processing chamber 20 at high temperature to remove the reaction products on the top surface, or to perform an etching process to remove the reaction products on the top surface.

Furthermore, since the shielding plate 50D is positioned on the top surface of the base 40D in a disassemble manner, the operators need only to replace the used shielding plate 50D with a new one before performing the next deposition process, instead of replacing the base 40D after each deposition process. Consequently, the thermal conductivity of the base 40D can be kept consistent, and the temperature of the wafer 12 on the base 40D can be easily controlled to increase the yield.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A wafer carrier, comprising:
a base having a top surface configured to retain a plurality of wafers, the base including a plurality of depressions configured to retain the wafers; and
a shielding plate positioned on the top surface of the base in a disassembled manner, where the shielding plate has a plurality of openings exposing the wafers.

2. The wafer carrier of claim 1, wherein the depth of the depression substantially equals the thickness of the wafer.

3. The wafer carrier of claim 1, further comprising a fixing member configured to fix the shielding plate on the base.

4. The wafer carrier of claim 1, wherein the shielding plate covers a portion of the base not configured to retain the wafers.

5. The wafer carrier of claim 1, wherein the openings are circular, and the shielding plate covers an edge portion of the wafers.

6. The wafer carrier of claim 1, wherein the base is a graphite base.

7. An epitaxy machine, comprising:
a processing chamber;
a plurality of inlets coupled to the processing chamber;
a shaft having an upper end in the processing chamber; and
a wafer carrier positioned on the upper end, the wafer carrier including:
a base having a top surface configured to retain a plurality of wafers, the base including a plurality of depressions configured to retain the wafers; and
a shielding plate positioned on the top surface of the base in a disassembled manner, with the shielding plate having a plurality of openings exposing the wafers.

8. The epitaxy machine of claim 7, wherein the depth of the depression substantially equals the thickness of the wafers.

9. The epitaxy machine of claim 7, further comprising a fixing member configured to fix the shielding plate on the base.

10. The epitaxy machine of claim 7, wherein the shielding plate covers a portion of the base not configured to retain the wafers.

11. The epitaxy machine of claim 7, wherein the openings are circular, and the shielding plate covers an edge portion of the wafers.

12. The epitaxy machine of claim 7, further comprising a heater positioned below the wafer carrier.

13. The epitaxy machine of claim 7, wherein the base is a graphite base.
